(19) United States
(12) Patent Application Publication
(10) Pub. No.: US 2015/0050105 A1
(43) Pub. Date: Feb. 19, 2015

(54) VAPOR DRYER MODULE WITH REDUCED PARTICLE GENERATION

(71) Applicants: Dan Zhang, Fremont, CA (US); Hui Chen, Burlingame, CA (US); Jim K. Atkinson, Los Gatos, CA (US); Hung Chih Chen, Sunnyvale, CA (US); Allen L. D'Ambra, Burlingame, CA (US)

(72) Inventors: Dan Zhang, Fremont, CA (US); Hui Chen, Burlingame, CA (US); Jim K. Atkinson, Los Gatos, CA (US); Hung Chih Chen, Sunnyvale, CA (US); Allen L. D'Ambra, Burlingame, CA (US)

(73) Assignee: APPLIED MATERIALS, INC., Santa Clara, CA (US)

(21) Appl. No.: 13/882,135

(22) PCT Filed: Jul. 25, 2012
(86) PCT No.: PCT/US12/48183

§ 371 Date: Nov. 5, 2014

Related U.S. Application Data
(60) Provisional application No. 61/638,936, filed on Apr. 26, 2012.

(51) Int. Cl. H01L 21/67; H01L 21/677; B25J 11/00; H01L 21/673; F26B 25/00; F26B 25/14

(52) U.S. Cl. CPC H01L 21/67034; F26B 25/001; F26B 25/14; B25J 11/0095; H01L 21/67057; H01L 21/67326; H01L 21/67748; H01L 21/67751
USPC 414/222.07

(57) ABSTRACT

Embodiments described herein generally relate to a vapor dryer module for cleaning substrates during a chemical mechanical polishing (CMP) process. In one embodiment, a module for processing a substrate is provided. The module includes a tank having sidewalls with an outer surface and an inner surface defining a processing volume, a substrate support structure for transferring a substrate within the processing volume, the substrate support structure having a first portion that is at least partially disposed in the processing volume and a second portion that is outside of the processing volume, and one or more actuators disposed on an outer surface of one of the sidewalls of the tank and coupled between the outer surface and the second portion of the support structure, the one or more actuators operable to move the support structure relative to the tank.

### BACKGROUND

1. Field

Embodiments of the invention generally relate to a vapor dryer module for cleaning substrates.

2. Description of the Related Art

In the manufacture of electronic devices on substrates, such as semiconductor devices, chemical mechanical polishing (CMP) is commonly utilized. The final cleaning step after polishing includes subjecting the substrate to an aqueous cleaning process in a vapor dryer module to remove residual particles from polishing and/or scrubbing, as well as eliminate fluid marks (i.e., watermarks, streaking and/or bath residue) from the substrate. As semiconductor device geometries continue to decrease, the importance of ultra clean processing increases. Aqueous cleaning of the substrate within a vapor dryer module containing fluid (or a bath) followed by a rinse achieves desirable cleaning levels. However, moving the substrate into and out of the vapor dryer module, as well as supporting the substrate within the vapor dryer module, requires transfer mechanisms inside the tank. The transfer mechanisms are typically mechanical devices that are prone to generating particles. As the final cleaning process is designed to remove particles from previous processes, it is desirable to minimize the generation of particles and/or control the propagation of residual particles during the final cleaning process.

What is needed is a vapor dryer module that minimizes and/or eliminates particle generation therein, and controls particles that may be transferred to the vapor dryer module from the substrate.

### SUMMARY

Embodiments described herein generally relate to a vapor dryer module for cleaning substrates during a chemical mechanical polishing (CMP) process. In one embodiment, a module for processing a substrate is provided. The module includes a tank having sidewalls with an outer surface and an inner surface defining a processing volume, a substrate support structure for transferring a substrate within the processing volume, the substrate support structure having a first portion that is at least partially disposed in the processing volume and a second portion that is outside of the processing volume, and one or more actuators disposed on an outer surface of one of the sidewalls of the tank and coupled between the outer surface and the second portion of the support structure, the one or more actuators operable to move the support structure relative to the tank.

In another embodiment, a module for processing a substrate is provided. The module includes a tank having sidewalls defining a processing volume, a substrate support structure for transferring a substrate within the processing volume, the substrate support structure having a first portion that is at least partially disposed in the processing volume and a second portion that is outside of the processing volume, a first actuator for moving the substrate support structure vertically relative to the tank, and a second actuator for moving the substrate support structure rotationally relative to the tank, wherein each of the first actuator and second actuator are disposed outside of the processing volume.

In another embodiment, a method for processing a substrate is provided. The method includes transferring a substrate into a first portion of a processing volume contained in a tank, securing the substrate in a substrate support structure at least partially disposed in the processing volume, wherein the substrate support structure is positioned in a first position having the substrate at a first orientation, tilting the substrate support structure to move the substrate to a second orientation utilizing a first actuator disposed outside of the processing volume, and lifting the substrate support structure to a second position that is vertically displaced from the first position using a second actuator that is disposed outside of the processing volume.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is an isometric view of a vapor dryer module according to embodiments described herein.

FIG. 2 is an isometric view of the vapor dryer module of FIG. 1.

FIG. 3 is an isometric top view of a portion of the vapor dryer module of FIG. 2.

FIG. 4 is an isometric cross-sectional view of the tank housing showing one embodiment of the support structure that may be utilized in the vapor dryer module of FIG. 1.

FIGS. 5A-5E are side cross-sectional views of the vapor dryer module showing embodiments of a cleaning cycle that may be performed in the vapor dryer module of FIG. 1.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a vapor dryer module for cleaning substrates during a chemical mechanical polishing (CMP) process. The vapor dryer module may be utilized to clean the substrate after polishing and a scrubbing process. The vapor dryer module includes a tank with minimal moving parts within the tank to minimize generation of particles during a cleaning process performed therein. Further, the vapor dryer module includes means for managing particles that may be present on an incoming substrate to prevent the particles from reattaching to the substrate. The vapor dryer module as provided herein may be utilized with a CMP cleaning system, such as a DESICA® cleaning system, available from Applied Materials, Inc. of Santa Clara, Calif., as well as cleaning systems from other manufacturers.

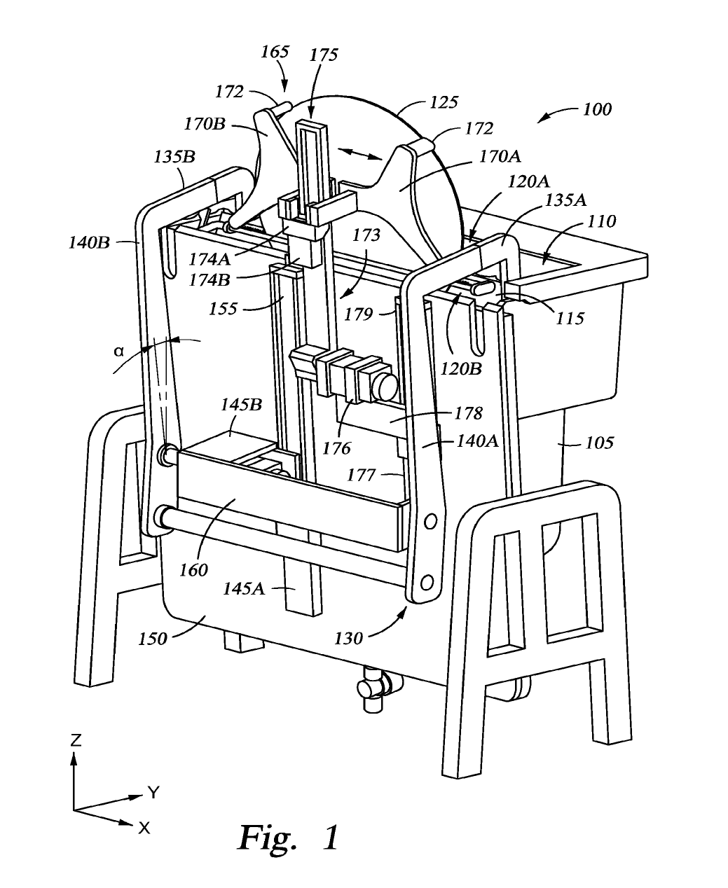

FIG. 1 is an isometric view of a vapor dryer module 100 according to embodiments described herein. The vapor dryer module 100 comprises a tank housing 105 configured as a tank that contains fluid in a processing volume 110. The processing volume 110 is bifurcated by a baffle plate 115 into an incoming (loading) portion 120A and an outgoing (unloading) portion 120B. The incoming portion 120A and the outgoing portion 120B are horizontally displaced in at least the Y direction. The vapor dryer module 100 also includes a support structure 130 that is at least partially disposed within the processing volume 110. The support structure 130 includes a first portion, which includes two arms 135A, 135B that are configured to support the substrate 125 within the tank volume 110. The support structure 130 also includes a second portion, which includes two arms 140A, 140B that are coupled to the arms 135A, 1358, respectively. Details of the structure and support function of the arms 135A, 135B will be described in later Figures.

The support structure 130 is coupled to one or more actuators adapted to position the support structure 130 rotationally and or linearly relative to the tank housing 105. For example, the support structure 130 is coupled to a first actuator 145A and a second actuator 145B disposed on an outer sidewall 150 of the tank housing 105. In one embodiment, the first actuator 145A engages a linear slide 155 disposed outside of the tank housing 105 that moves the support structure 130 linearly (Z direction) relative to the tank housing 105. The second actuator 145B may be coupled to a cross-member 160 positioned between the arms 140A and 140B. The second actuator 145B is utilized to rotate or tilt the support structure 130 relative to the tank housing 105, such as along the X axis. The first actuator 145A and the second actuator 145B may be powered pneumatically, hydraulically, electrically, or combinations thereof. The second actuator 145B may selectively engage with the linear slide 155 and rotational force is imparted between the linear slide 155 and the cross-member 160 to cause the support structure 130 to rotate relative to the tank housing 105. In one embodiment, the second actuator 145B rotates the support structure 130 through an angle α, which may be about 0 degrees to about 12 degrees from normal, for example about 9 degrees from normal.

The vapor dryer module 100 also includes a gripping device 165 adjacent an opening of the outgoing portion 120B of the processing volume 110. The gripping device 165 includes two arms 170A, 170B that are movable relative to each other. The arms 170A, 170B include grippers 172 that engage an edge of the substrate 125. Each arm 170A, 170B is coupled to an actuator 174A that moves one or both of the arms 170A, 170B toward and away from each other in order to engage and disengage the edge of the substrate 125. The gripping device 165 also includes a rotation mechanism 173 that includes a support bar 175 and an actuator 176. The actuator 176 rotates the support bar 175 and the gripping device 165 about 0 degrees from normal to about 90 degrees from normal. The gripping device 165 also includes a linear actuator 174B that may operate to move the gripping device 165 and the actuator 174A along the length of the support bar 175 in order to position the gripping device 165 in the X-Z plane, the X-Y plane, or any direction therebetween, depending upon the angle of rotation of the rotation mechanism 173. The rotation mechanism 173 may also be raised or lowered vertically by an actuator 177 that is disposed outside of the processing volume 110. The actuator 177 is coupled between the outer sidewall 150 and the actuator 176 by a support member 178. The actuator 177 may raise or lower the rotation mechanism 173 and the gripping device 165 to facilitate transfer of the substrate 125. The actuator 177 may interface with a linear slide 179 coupled to the outer sidewall 150 of the tank housing 105. The actuator 174A, the actuator 174B, the actuator 176 and the actuator 177 may be powered pneumatically, hydraulically, electrically, and combinations thereof.

In operation, the substrate 125 is transferred into the incoming portion 120A by an end effector (not shown) and transferred from the end effector to a first position between the two arms 135A, 135B of the support structure 130 that are disposed in the processing volume 110. The substrate 125 is held in this lowered position by the support structure 130 during processing in the processing volume 110. During processing, the support structure 130 (and the substrate 125) may move (i.e., tilt or rotate) from the first position to a second position by motive force from the second actuator 145B. After moving to the second position, the first actuator 145A may provide motive force to raise the support structure 130 (and substrate 125) to a third position where the substrate 125 may be transferred from the support structure 130 to the gripping device 165. Once the gripping device 165 engages the substrate 125, the support structure 130 may be lowered into the processing volume 110 (shown in FIG. 1) to receive another incoming substrate.

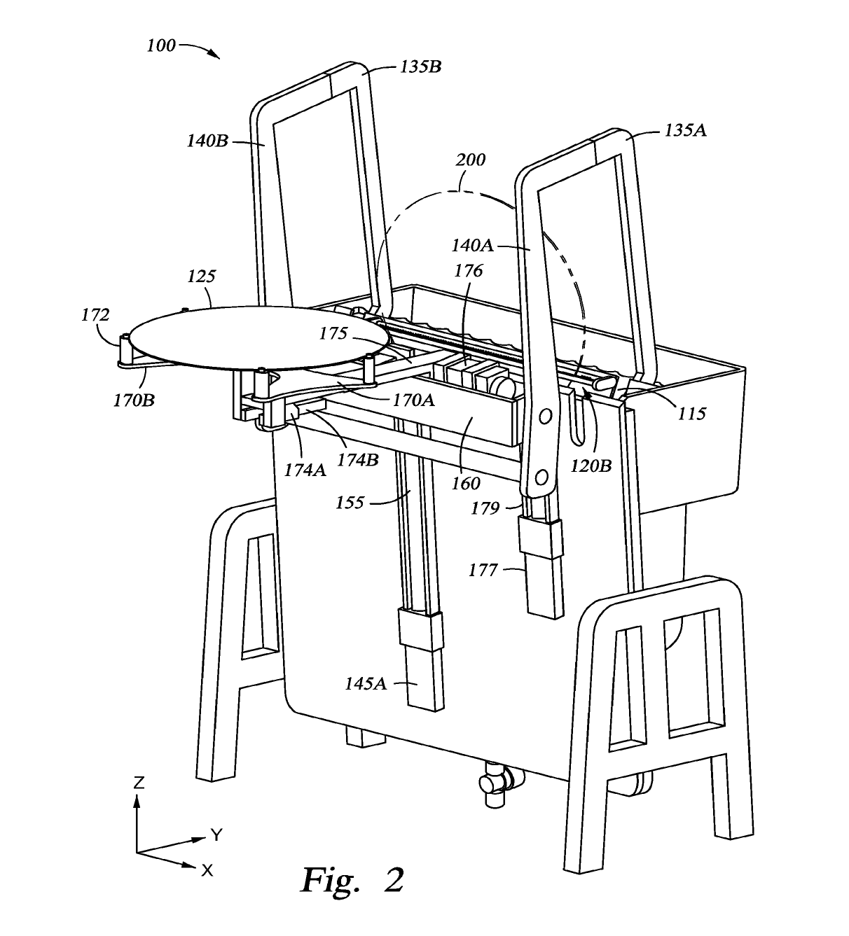

FIG. 2 is an isometric view of the vapor dryer module 100 of FIG. 1 showing the substrate 125 rotated in the gripping device 165 to a fourth position. The fourth position may be substantially horizontal (i.e., 90 degrees from normal) to facilitate transfer of the substrate 125 from the gripping device 165 to a robot blade (not shown). FIG. 2 also shows a substrate 200 (in phantom) in the third position similar to the substrate 125 shown in FIG. 1 with the exception of the substrate 200 being supported by the support structure 130. The substrate 200 is in a position for transfer to the gripping device 165. The support structure 130 is raised in this Figure to show the position of the support structure 130 for transfer of the substrate 125 to the gripping device 165. Once the substrate 125 is removed from the gripping device 165, the gripping device 165 may be rotated to a substantially vertical position. The arms 170A, 170B may be moved away from each other to provide clearance for the edge of the substrate 200. Movement of one or both of the gripping device 165 and the support structure 130 may be utilized to bring the gripping device 165 and the substrate 200 in proximity with each other. When the gripping device 165 and the substrate 200 are in proximity, the arms 170A, 170B may be brought together to engage the substrate 200 edge. The gripping device 165 may then rotate the substrate 200 to the fourth position for transfer, and the support structure 130 may be lowered into the processing volume 110 to receive another substrate.

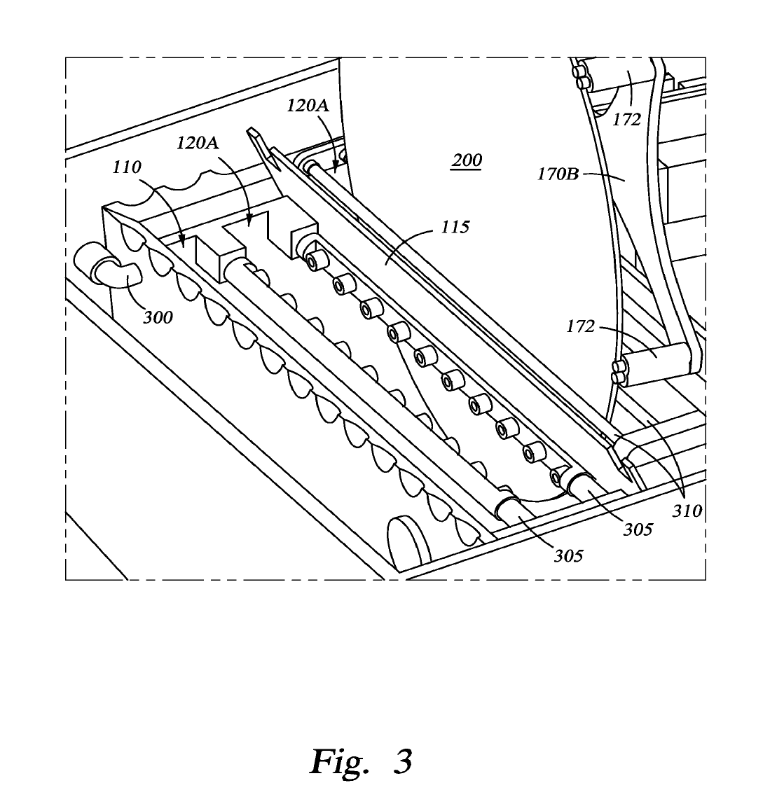

FIG. 3 is an isometric top view of a portion of the vapor dryer module 100 of FIG. 2. In this view, the grippers 172 of the gripping device 165 are shown engaging the substrate 200 edge. Also shown are the incoming portion 120A and the outgoing portion 120B of the processing volume 110. The incoming portion 120A and the outgoing portion 120B are at least partially separated by the baffle plate 115. In operation, the processing volume 110 would be filled with fluid to a level near a drain conduit 300. The baffle plate 115 extends at least partially below this fluid level and is utilized to isolate the incoming portion 120A from the outgoing portion 120B. When a substrate is transferred into the incoming portion 120A, the substrate passes between a pair of spray bars 305 to spray a fluid such as deionized water onto the incoming substrate. As the incoming substrate may include residual particles, the particles become dislodged and typically float on the surface of the fluid. The baffle plate 115 keeps the floating particles from entering the outgoing portion 120B. The baffle plate 115 also minimizes splashing or wave movement from entering into the outgoing portion 120B. This allows the outgoing portion 120B to remain relatively particle free and provides a constant water level in the outgoing portion 120B. As the substrate exits the processing volume 110 through the outgoing portion 120B, the substrate passes between spray bars 310 which spray a fluid such as isopropyl alcohol (IPA) onto the outgoing substrate. The constant water level in the outgoing portion 120B may assist in drying of the substrate and prevention of watermark defects on the substrate. Additionally, a cover (partially shown in FIG. 1) having openings for the incoming portion 120A and the outgoing portion 120B may be utilized to cover the remainder of the processing volume 110. The cover may be in two pieces that will provide easy disassembly and access to the spray bars 305 and 310.

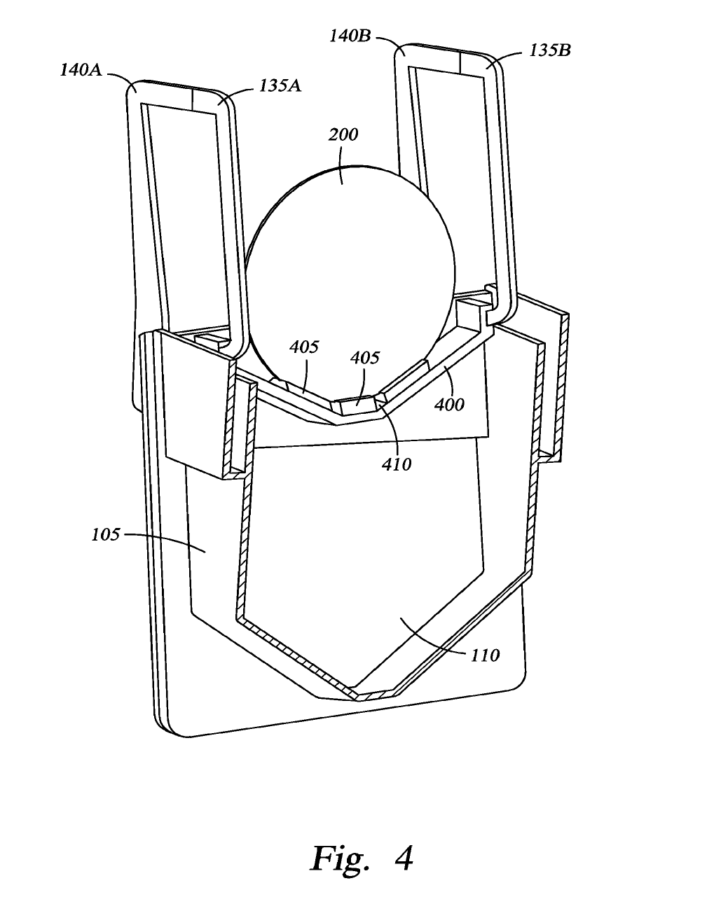

FIG. 4 is an isometric cross-sectional view of the tank housing 105 showing one embodiment of the support structure 130 that may be utilized in the vapor dryer module 100 of FIG. 1. The support structure 130 includes arms 135A, 135B and arms 140A, 140B. In this embodiment, the arms 135A, 135B are coupled to a substrate supporting structure, such as a cradle 400. The cradle 400 includes one or more raised structures 405 that each include a channel formed therein to receive the substrate 200 edge. The channels are configured to hold the substrate in a substantially vertical orientation without clamping the substrate. Drainage channels 410 may be formed between the structures 405 to assist in draining fluid. The arms 135A, 135B may comprise a different material than the material of the arms 140A, 140B. The arms 135A, 135B may be made of a process resistant polymeric material, such as polyetheretherketone (PEEK) while the arms 140A, 140B are made of a more resilient metallic material, such as anodized aluminum.

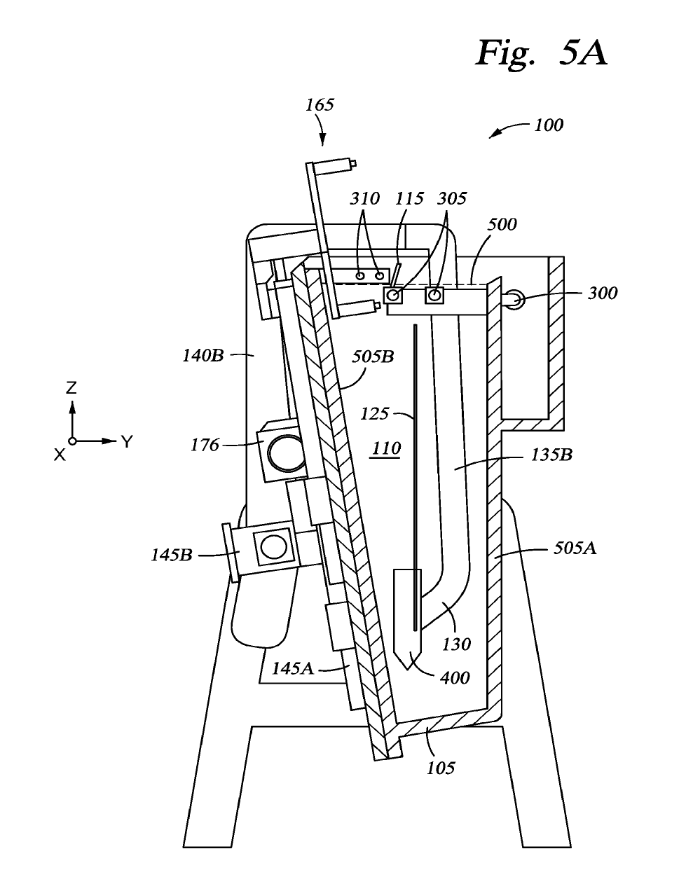

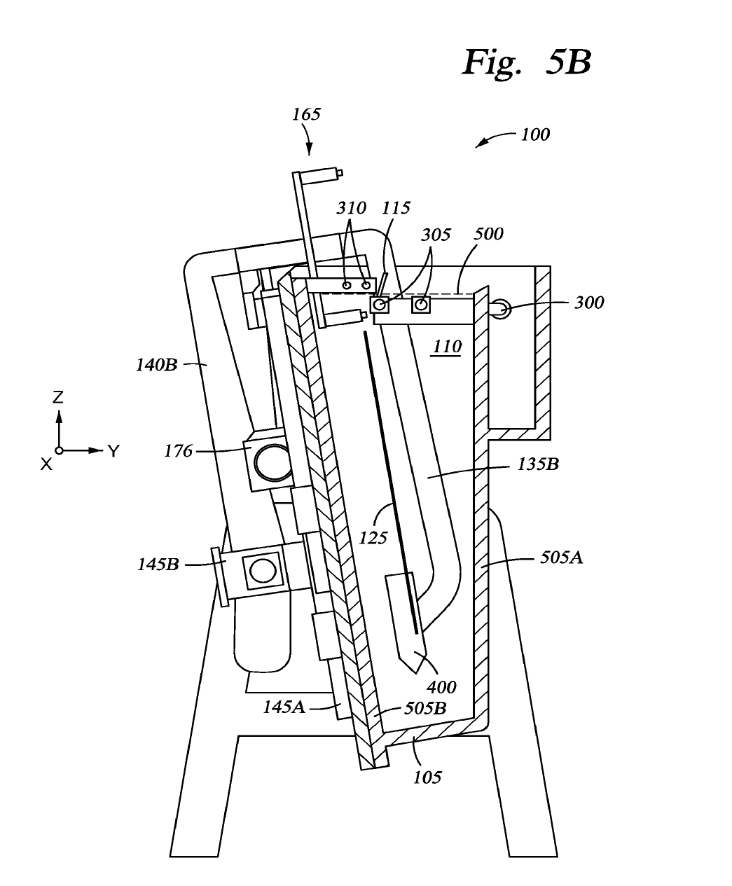

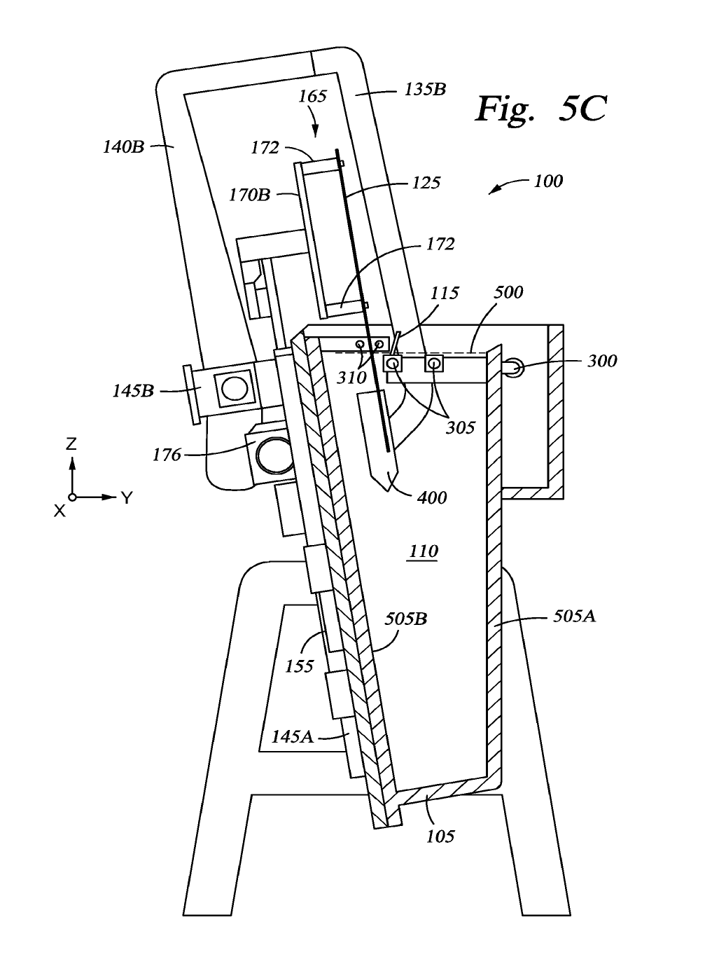

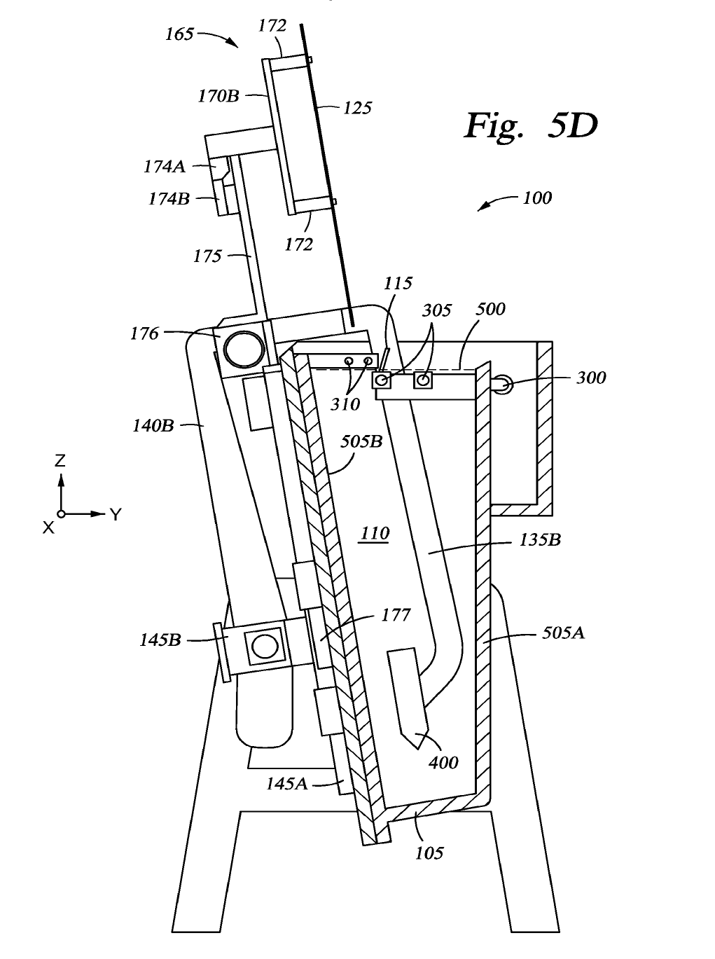

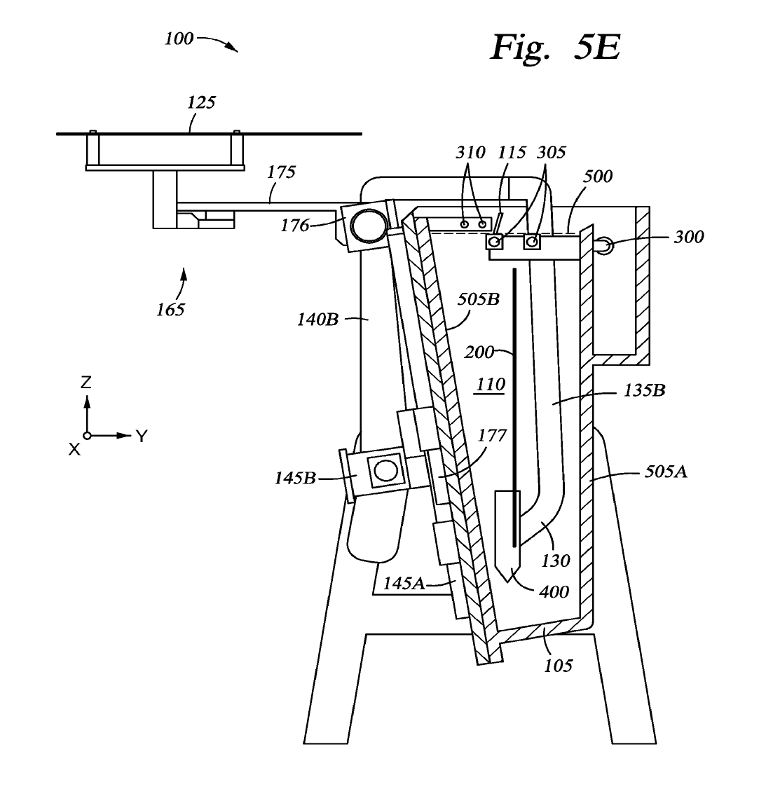

FIGS. 5A-5E are side cross-sectional views of the vapor dryer module 100 showing embodiments of a cleaning cycle that may be performed in the vapor dryer module 100 of FIG. 1. FIG. 5A shows a substrate 125 submerged in the processing volume 110 below a fluid level 500. The substrate 125 may be transferred into the vapor dryer module 100 by an end effector (not shown) that lowers the substrate 125 at least partially into the processing volume 110 and transfers the substrate 125 to the support structure 130. In one embodiment, the substrate 125 enters the processing volume 110 between the spray bars 305 and is supported by the end effector prior to transfer from the end effector to the cradle 400 of the support structure 130. In another embodiment, the support structure 130 may be raised and the substrate 125 may be transferred to the cradle 400 so the end effector does not enter the processing volume 110. The support structure 130 then lowers the substrate 125 into between the spray bars 305 and into the processing volume 110. Regardless of the transfer method, the substrate 125 is placed into and supported by the cradle 400 in the submerged position. The substrate 125 is in a first position and orientation in the processing volume 110. The substrate 125 in this position may be oriented parallel to a first sidewall 505A of the tank housing 105.

FIG. 5B shows the substrate 125 rotated into a second position and orientation. Rotation is provided by the actuator 145B coupled to the support structure 130. In one embodiment, the angle of rotation is about 6 degrees to about 12 degrees from the first position (i.e. substantially normal), such as about 9 degrees from the first position. The substrate 125 in this position may be oriented parallel to a second sidewall 505B of the tank housing 105.

FIG. 5C shows the substrate raised to a third position, which may be a transfer position for transferring the substrate 125 to the gripping device 165. Actuation of the actuator 145A raises the support structure 130, which raises the substrate 125 to this position. The substrate 125 may be raised to the third position in the second orientation. The arms 170A and 170B (only 170B is shown) of the gripping device 165 may be spaced apart to allow the substrate 125 to at least partially pass the grippers 172 on the arms 170A, 170B. In this orientation, the substrate 125 may be raised to a position between the grippers 172. Once the substrate 125 is between opposing grippers 172, the arms 170A, 170B of the gripping device 165 may be moved together to grip the substrate 125 as shown in FIG. 5D.

FIG. 5D shows the substrate 125 transferred to the gripping device 165. The substrate 125 may be raised from the tank housing 105 to a distal end of the support bar 175 by the actuator 174B, as shown. It is to be noted that raising lowering and pivoting of the support structure 130 is independent of any movement of the support structure 130, and vice versa. As such, after transfer of the substrate 125, the support structure 130 may be moved linearly and/or rotated to prepare for transfer of an incoming substrate.

FIG. 5E shows the substrate 125 in the gripping device 165 that is rotated for transfer to a robot blade (not shown). FIG. 5E also shows the support structure 130 in the first position having a substrate 200 thereon for beginning the processing sequence. The substrate 125 is in a fourth position and a third orientation. The orientation of the substrate 125 is substantially horizontal. The third orientation may be substantially orthogonal to the substrate 200 in the first position.

It is to be noted, the support structure 130 nor the substrate 125 (or 200) does not contact any portion of the tank housing 105 during the sequence shown in FIGS. 5A-5E, which markedly reduces particle generation.

The vapor dryer module 100 as described herein provides improved processing by providing substrate transfer mechanisms outside of the processing volume of the tank. Benefits include improved particle management by minimizing particle generation, reduced vibration, increased reliability and servicing. The independent movement of the gripping device 165 and the support structure 130 also improves throughput.

While the foregoing is directed to embodiments of the present invention, other and further embodiments of the invention may be devised without departing from the basic scope thereof, and the scope thereof is determined by the claims that follow.

1. A module for processing a substrate, comprising
a tank having sidewalls with an outer surface and an inner surface defining a processing volume;
a substrate support structure for transferring a substrate within the processing volume, the substrate support structure having a first portion that is at least partially disposed in the processing volume and a second portion that is outside of the processing volume; and
one or more actuators disposed on an outer surface of one of the sidewalls of the tank and coupled between the outer surface and the second portion of the support structure, the one or more actuators operable to move the support structure relative to the tank.

2. The module of claim 1, further comprising a linear slide mechanism disposed on the outer surface of one of the sidewalls of the tank and coupled to one of the one or more actuators.

3. The module of claim 2, wherein the one or more actuators comprise a first actuator to move the substrate support structure rotationally relative to the tank.

4. The module of claim 3, wherein the one or more actuators comprise a second actuator to move the substrate support structure vertically relative to the tank.

5. The module of claim 1, wherein the first portion of the support structure comprises two arms that terminate at a support cradle for holding the substrate.

6. The module of claim 5, wherein the first portion of the substrate support structure comprises a first material and the second portion of the substrate support structure comprises a second material, the first material being different from the second material.

7. The module of claim 6, wherein the first material comprises a polymeric material.

8. The module of claim 1, wherein the processing volume is at least partially separated by a baffle plate.

9. A module for processing a substrate, comprising
a tank having sidewalls defining a processing volume;
a substrate support structure for transferring a substrate within the processing volume, the substrate support structure having a first portion that is at least partially disposed in the processing volume and a second portion that is outside of the processing volume;
a first actuator for moving the substrate support structure vertically relative to the tank; and
a second actuator for moving the substrate support structure rotationally relative to the tank, wherein each of the first actuator and second actuator are disposed outside of the processing volume.

10. The module of claim 9, wherein the first portion of the support structure comprises two arms that terminate at a support cradle for holding the substrate.

11. The module of claim 10, wherein the one of the first actuator or the second actuator maintains the two arms in a spaced apart relation to in inner surface of the sidewalls of the tank.

12. The module of claim 9, further comprising a linear slide mechanism disposed on an outer surface of one of the sidewalls of the tank and coupled to one or both of the first actuator and the second actuator.

13. The module of claim 9, wherein the first portion of the substrate support structure comprises a first material and the second portion of the substrate support structure comprises a second material, the first material being different from the second material.

14. The module of claim 6, wherein the first material comprises a polymeric material and the second material comprises aluminum.

15. The module of claim 9, further comprising a linear slide mechanism disposed on the outer surface of one of the sidewalls of the tank and coupled to the first actuator.
